(19) United States
(12) Patent Application Publication
(10) Pub. No.: US 2023/0215757 A1
(43) Pub. Date: Jul. 6, 2023

(54) Transfer System and Transfer Method

(71) Applicant: CHONGQING KONKA PHOTOELECTRIC TECHNOLOGY RESEARCH INSTITUTE CO., LTD., Chongqing (CN)

(72) Inventors: CHIA-HSIU CHANG, Chongqing (CN); Ruilin XU, Chongqing (CN)

(21) Appl. No.: 17/611,915

(22) PCT Filed: Sep. 21, 2020
(86) PCT No.: PCT/CN2020/116578

§ 371 Date: Nov. 17, 2021

(51) Int. Cl. H01L 21/683; H01L 33/00; H01L 25/075

(52) U.S. Cl. CPC H01L 21/6835; H01L 33/0093; H01L 25/0753; H01L 2221/68322; H01L 2221/68368

(57) ABSTRACT

Provide are a transfer system and a transfer method. The transfer system is configured to transfer chips and includes a temporary substrate and a transfer device. The temporary substrate has a first surface and a second surface opposite to each other. There is a first angle between the second surface and the first surface. The transfer device has a transfer substrate and a plurality of transfer heads provided on the transfer substrate. The transfer substrate has a third surface and a fourth surface opposite to each other, and there is a second angle between the fourth surface and the third surface. The plurality of transfer heads are located at intervals on the fourth surface, and a side surface of the above-mentioned transfer head that faces away from the transfer substrate is parallel to the fourth surface.

### CROSS-REFERENCE TO RELATED APPLICATION

The present disclosure claims priority to Chinese Patent Application No. 202010997976.6, filed to the China National Intellectual Property Administration on Sep. 21, 2020, the disclosure of which is hereby incorporated by reference in its entirety.

### TECHNICAL FIELD

The disclosure relates to the field of display, and particularly to a transfer system and a transfer method.

### BACKGROUND

Several pixel regions are arranged on a MICRO-Light Emitting Diode (LED) display panel, and each of the pixel regions includes a red LED chip, a blue LED chip, a green LED chip. In the manufacture of a display, the three types of LED chips which are the red LED chip, the blue LED chip, the green LED chip are required to be transferred from respective growth substrates to a display back plate.

An existing mass transfer method includes the following steps.

These chips are firstly transferred onto a first adhesive layer of a first temporary substrate.

the LED chips are transferred through a transfer substrate onto a structure such as the display back plate. The specific embodiment is that the transfer substrate is adhered to the LED chips through a second adhesive layer at a surface of the transfer substrate, and then the first adhesive layer on the first temporary substrate is selectively irradiated by a laser so as to be peptized, so that the first adhesive layer is carbonized or gasified, and thus the LED chip is disengaged from the first temporary substrate and is adhered to the transfer substrate. However, the peptization process is complicated, so there is a difficulty in stably implementing the mass transfer, which is not conductive to mass production of the MICRO-LED display.

Therefore, how to reduce the difficulty for disengaging the chip from the temporary substrate is the problem that needs to be solved.

### SUMMARY

In view of shortcomings of the above-mentioned conventional art, the object of this application is to provide a transfer system and a transfer method to solve the problem of disengaging the chip from the temporary substrate.

A transfer system, which is configured to transfer a chip, includes a temporary substrate and a transfer device. The temporary substrate has a first surface and a second surface opposite to each other. There is a first angle between the second surface and the first surface. The first angle is greater than 0° and less than 90°. The transfer device has a transfer substrate and a plurality of transfer heads provided on the transfer substrate. The transfer substrate has a third surface and a fourth surface opposite to each other, and there is a second angle between the fourth surface and the third surface. The second angle is greater than 0° and less than 90°. The plurality of transfer heads are located at intervals on the fourth surface, and a side surface of the transfer head that faces away from the transfer substrate is parallel to the fourth surface.

In the above-mentioned transfer system, the temporary substrate and the transfer device are included. There is an angle between the first surface and the second surface of the temporary substrate, that is, the second surface is an inclined surface relative to the first surface, and the first surface is also an inclined surface relative to the second surface. In this way, when the chip is provided at the first surface or the second surface of the temporary substrate, since the surface where it is located is an inclined surface, compared to a non-inclined surface in the conventional art, the chip is more likely disengaged from the inclined surface. The temporary substrate may reduce the difficulty for disengaging the chip from the temporary substrate. Further, on the above-mentioned transfer substrate, there is also an angle between the above-mentioned third surface and the above-mentioned fourth surface. The above-mentioned plurality of transfer heads are located at intervals on the above-mentioned fourth surface, and the side surface of the transfer head that faces away from the transfer substrate is parallel to the fourth surface. In this way, the transfer device may be better matched to the temporary substrate so as to further simplify the transfer process.

In an embodiment, the first angle is equal to the second angle. This makes it possible to make the degree of matching between the transfer device and the temporary substrate higher, so that the two are more closely matched during the transfer process to simplify the transfer process of the chip.

Based on the same inventive concept, the application also provides a chip transfer method, which is applied to the transfer system. The transfer method includes the following operations. A first adhesive layer is formed on the second surface of the temporary substrate. The chip on the growth substrate is adhered onto the temporary substrate through the first adhesive layer. The first adhesive layer adhered to the chip is made into a plurality of weakened structures. A second adhesive layer is applied to the transfer head, and the chip on the temporary substrate is adhered by the second adhesive layer. A first predetermined force is applied at a predetermined end of the transfer device so that the weakened structure is broken, and thus the chip after disengaged from the temporary substrate is transferred onto the transfer device. The chip on the transfer device is transferred onto a predetermined structure.

In the above-mentioned transfer method, the first predetermined force is applied at the predetermined end of the transfer device so that the chip is disengaged from the weakened structure, thereby the chip being transferred onto the transfer device, and since the chip is located at the inclined surface of the temporary substrate, and the first predetermined force is applied at the predetermined end of the transfer device. In this way, the weakened structure bears force at a single point and is more easily disengaged from the chip. This method transfers the chip from the temporary substrate onto the transfer device by forming a weakened structure and applying the relatively small first predetermined force. In the method, the peptization process in the conventional art is avoided. The method makes the chip transferred onto the transfer device by a simple process, i.e., the difficulty for disengaging the chip from the temporary substrate is reduced and it is conductive to mass production of the displays.

In an embodiment, the first adhesive layer adhered to the chip being made into the plurality of weakened structure includes the following operations. A portion of the first adhesive layer is removed, so that the remaining first adhesive layer forms the plurality of weakened structures.

In an embodiment, the operation of removing the portion of the first adhesive layer so that the remaining first adhesive layer forms the plurality of weakened structure includes the following operations. A barrier member is provided on the surface of the chip away from the temporary substrate. The barrier member includes a plurality of openings provided at intervals, and projections of the openings on the temporary substrate are located in an intermediate region in one-to-one correspondence. The intermediate region is a surface region of the temporary substrate between the adjacent two chips. A solvent is injected from the opening between the adjacent two chips, so that the solvent dissolves the portion of the first adhesive layer so as to form the plurality of weakened structures. The method is more easily implemented, and the weakened structure of a predetermined size and a predetermined shape may be further ensured at the same time.

In an embodiment, a sectional area of the opening in a direction perpendicular to the second surface gradually increases. This makes it possible to gradually decrease the force required for disengaging the weakened structure from the corresponding chip, thereby further ensuring that applying the relatively small first predetermined force may better disengage all the weakened structures from the corresponding chips.

In an embodiment, a second adhesive layer being applied to the transfer head, and the chip on the temporary substrate being adhered by the second adhesive layer includes the following operations. The second adhesive layer on the transfer head is aligned with the chip so that the third surface is parallel to the first surface, and the fourth surface is parallel to the second surface. A second predetermined force is applied to the transfer device so that the second adhesive layer is adhered to the chip on the temporary substrate. In this method, the degree of matching between the shape of the transfer substrate and the shape of the temporary substrate is relatively high, and the transfer head is provided on the inclined surface of the transfer substrate. When the second predetermined force is applied to the transfer substrate of the transfer device, a downward second force is applied directly to the third surface, so that the scheme is more convenient for applying the second predetermined force, and further simplifying the transfer method.

In an embodiment, the first predetermined force being applied to the predetermined end of the transfer device so that the weakened structure is broken, and then the chip after disengaged from the temporary substrate is transferred onto the transfer device includes the following operations. The first predetermined force is applied to a first end on the transfer substrate so that the transfer substrate begins to rotate about an axis, and the weakened structures are subsequently broken in ascending order of a distance from the first end of the transfer substrate. The thickness of a first end of the temporary substrate is less than the one of a second end of the temporary substrate. The predetermined axis is on a plane where the third surface is located and is perpendicular to a sidewall of the transfer substrate. In this way, the first end of the transfer substrate is an end corresponding to the first end of the temporary substrate. The first predetermined force is applied to the first end of the transfer substrate, so that the weakened structure that is located at a place of the temporary substrate whose thickness is relatively small is firstly disengaged from the corresponding chip. This makes it possible to adopt a smaller predetermined force to disengage the weakened structure from the corresponding chip.

In an embodiment, the operation of using the first adhesive layer to adhere the chip on the growth substrate onto the temporary substrate includes the following operations. A chip source structure is attached to the first adhesive layer so that the chip in the chip source structure is adhered onto the surface of the first adhesive layer. The chip source structure includes the growth substrate and the plurality of chips provided on the growth substrate. The growth substrate is removed.

In an embodiment, the growth substrate is a sapphire growth substrate. The operation of removing the growth substrate includes the following operations. The growth substrate is irradiated by a laser, and the growth substrate after irradiated by the laser is peeled.

In an embodiment, the operation of transferring the chip on the transfer device onto the predetermined structure includes the following operation. The transfer device provided with the chip is bonded to the predetermined structure, and the chip is in contact with the predetermined structure, and the transfer device is removed.

In an embodiment, the predetermined structure includes a display back plate.

In an embodiment, the chip includes at least one of an LED chip, a Micro LED chip, and a Mini LED chip.

### BRIEF DESCRIPTION OF THE DRAWINGS

FIG. 1 is a schematic structural diagram of a temporary substrate in a transfer system provided by an embodiment of this application.

FIG. 2 is a schematic structural diagram of a transfer device in a transfer system provided by an embodiment of this application.

FIG. 3 is a schematic structural diagram after a chip source structure is adhered to a first adhesive layer.

FIG. 4 is a schematic structural diagram after a growth substrate in FIG. 3 is removed.

FIG. 5 is a schematic structural diagram after a weakened structure is formed after a portion of a first adhesive layer in FIG. 4 is removed.

FIG. 6 is a schematic diagram of forming an attachment structure after a first to-be-attached structure is attached to a second to-be-attached structure.

FIG. 7 is a schematic structural diagram after a first predetermined force is applied to FIG. 6.

FIG. 8 is a schematic diagram of transferring a chip onto a predetermined structure.

FIG. 9 is a schematic structural diagram after a transfer device in FIG. 8 is removed.

### DESCRIPTION OF REFERENCE NUMERALS

Temporary substrate 10; First surface 11; Second surface 12; Transfer device 20; Transfer substrate 12; Transfer head 22; Third surface 201; Fourth surface 202; First adhesive layer 30; Weakened structure 31; Chip source structure 40; Growth substrate 41; Chip 42; Predetermined structure 50.

### DETAILED DESCRIPTION OF THE EMBODIMENTS

In order to understand the application, the application will be further described with reference to the related drawings. The preferred embodiment of the application is given in the drawings. However, the application may be implemented in many different forms, and is not limited to the embodiments described herein. Conversely, the purpose of providing these embodiments is to make the understanding of the disclosure of the application more thoroughly.

Unless otherwise defined, all technical and scientific terms used herein are the same as those skilled in the art of this application typically understand. The terms used in the specification of the application are for the purpose of describing particular embodiments only and are not intended to limit the application.

As illustrated in the background, in a process of transferring a chip in a conventional art, a peptization process needs to be implemented, which is relatively complicated, thereby causing the transfer process of the chip to be more complicated.

Based on this, the present application is desirable to provide a solution that solves the above-mentioned technical problem, which will be set forth in the following embodiments.

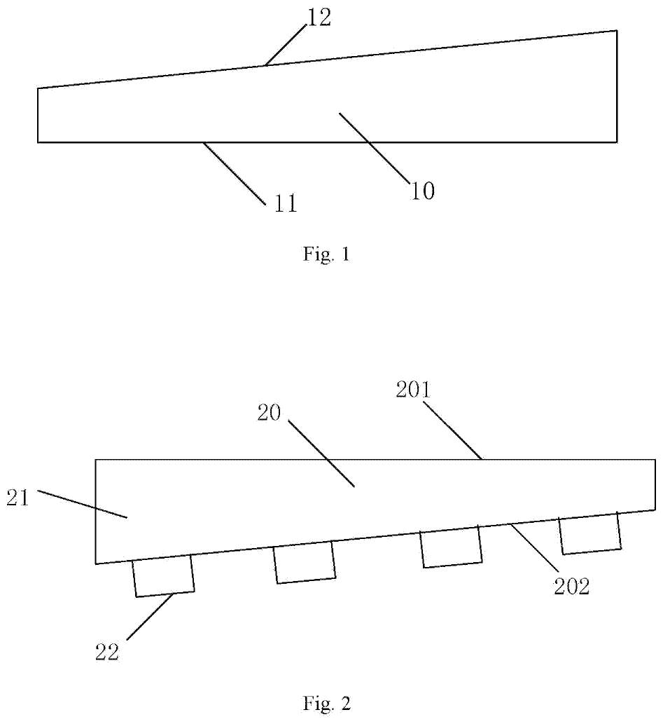

In a typical embodiment of the application, a transfer system is provided. The above-mentioned transfer system is configured to transfer a chip. The transfer system includes a temporary substrate 10 and a transfer device. As shown in FIG. 1, the temporary substrate 10 has a first surface 11 and a second surface 12 opposite to each other. There is a first angle between the second surface 12 and the first surface 11. The above-mentioned first angle is greater than 0° and less than 90°. the transfer device 20, as shown in FIG. 2, the transfer device 20 has a transfer substrate 21 and a plurality of transfer heads 22 provided on the transfer substrate 21. The above-mentioned transfer device 20 has a third surface 201 and a fourth surface 202 opposite to each other, and there is a second angle between the above-mentioned fourth surface 202 and the above-mentioned third surface 201. The above-mentioned second angle is greater than 0° and less than 90°. The above-mentioned plurality of transfer heads 22 are located at intervals on the above-mentioned fourth surface 202, and a side surface of the above-mentioned transfer head 22 that faces away from the above-mentioned transfer substrate 21 is parallel to the above-mentioned fourth surface 202.

In the above-mentioned transfer system, the temporary substrate and the transfer device are included. There is an angle between the first surface and the second surface of the temporary substrate, that is, the second surface is an inclined surface relative to the first surface, and the first surface is also an inclined surface relative to the second surface. In this way, when the chip is provided at the first surface or the second surface of the temporary substrate, since a surface where it is located is an inclined surface, compared to a non-inclined surface in the conventional art, the chip is more likely to be disengaged from the inclined surface. The temporary substrate may reduce the difficulty for disengaging the chip from the temporary substrate. Further, on the above-mentioned transfer substrate, there is also an angle between the above-mentioned third surface and the above-mentioned fourth surface. The above-mentioned plurality of transfer heads are located at intervals on the above-mentioned fourth surface, and the side surface of the above-mentioned transfer head that faces away from the above-mentioned transfer substrate is parallel to the above-mentioned fourth surface. In this way, the transfer device may be better matched to the temporary substrate so as to further simplify the transfer process.

In another embodiment of the application, the above-mentioned first angle is equal to the above-mentioned second angle. This makes it possible to make the degree of matching between the transfer device and the temporary substrate higher, so that the two are more closely matched during the transfer process to simplify the transfer process of the chip.

Another typical embodiment of the application provides a chip transfer method. The transfer method includes the following steps.

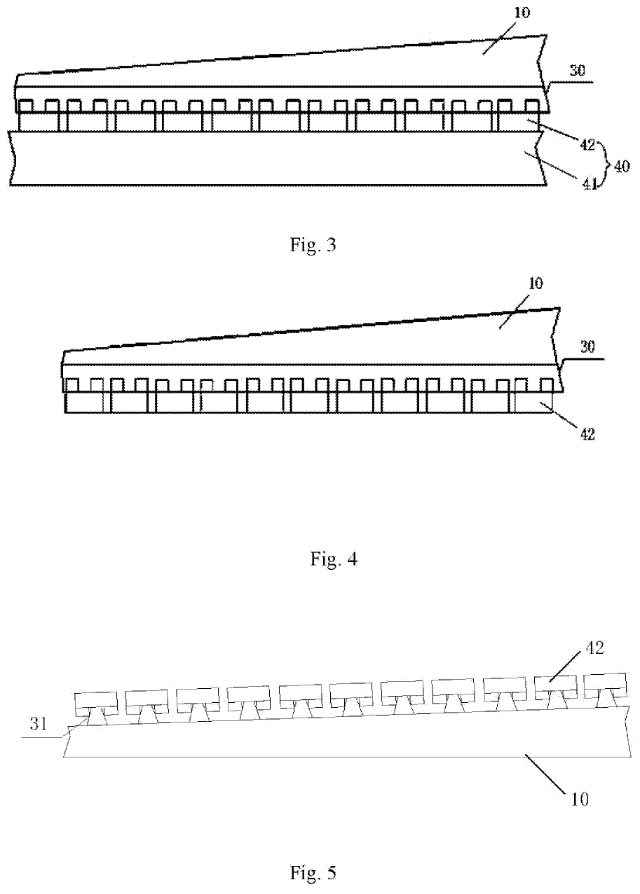

At S101, a first adhesive layer 30 is formed on the above-mentioned second surface 12 of the above-mentioned temporary substrate 10. The above-mentioned first adhesive layer 30 is used to adhere a chip 42 on a growth substrate onto the above-mentioned temporary substrate 10, as shown in FIG. 3 and FIG. 4.

At S102, the above-mentioned first adhesive layer 30 adhered to the above-mentioned chip 42 is made into a plurality of weakened structures 31, as shown in FIG. 5.

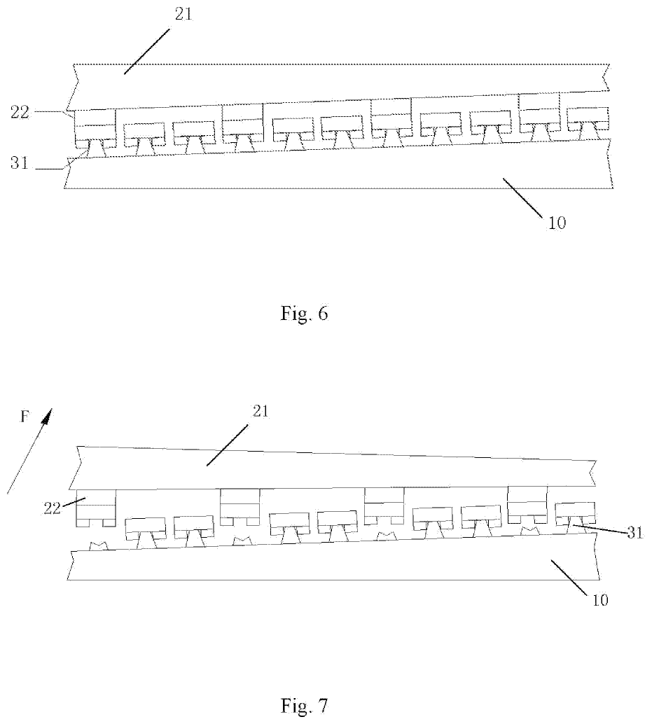

At S103, a second adhesive layer is applied on the above-mentioned transfer head 22. The above-mentioned chip 42 on the above-mentioned temporary substrate 10 is adhered by the above-mentioned second adhesive layer, as shown in FIG. 6.

At S104, a first predetermined force is applied to a predetermined end of the above-mentioned transfer device 20 so that the above-mentioned weakened structure 31 is broken, and thus the above-mentioned chip 42 after disengaged from the above-mentioned temporary substrate is transferred onto the above-mentioned transfer device, as shown in FIG. 7.

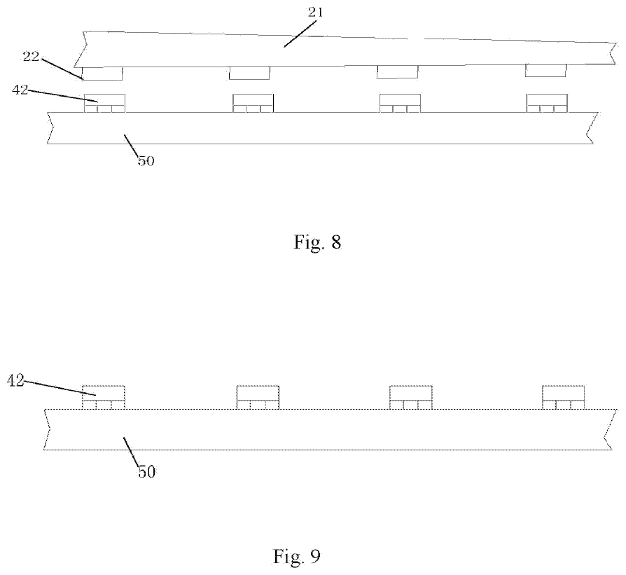

At S105, the above-mentioned chip 42 on the above-mentioned transfer device 20 is transferred onto a predetermined structure 50, as shown in FIG. 8 and in FIG. 9.

In the above-mentioned transfer method, the first predetermined force is applied at the predetermined end of the transfer device so that the chip is disengaged from the weakened structure, thereby the chip being transferred onto the transfer device, and since the chip is located at the inclined surface of the temporary substrate, and the first predetermined force is applied at the predetermined end of the transfer device. In this way, the weakened structure bears force at a single point and is more easily disengaged from the chip. This method transfers the chip from the temporary substrate onto the transfer device by forming a weakened structure and applying the relatively small first predetermined force. In the method, the peptization process in the conventional art is avoided. The chip is transferred onto the transfer device by the simple process, i.e., the difficulty for disengaging the chip from the temporary substrate is reduced and it is conductive to mass production of displays.

In a specific embodiment of the application, the above-mentioned operation of the first adhesive layer 30 adhered to the chip 42 being made into the plurality of weakened structure 31 includes the following operation. A portion of the above-mentioned first adhesive layer 30 is removed, so that the above-mentioned remaining first adhesive layer 30 forms the above-mentioned plurality of weakened structures 31.

In the actual application process, the portion of the first adhesive layer may be removed by any feasible manner so as to form the plurality of weakened structures. Those skilled in the art may select, according to the actual situation, a suitable method to form the plurality of weakened structures.

In a specific embodiment of the application, the operation of removing the portion of the above-mentioned first adhesive layer so that the above-mentioned remaining first adhesive layer forms the plurality of weakened structure includes the following operations. A barrier member is provided on a surface of the above-mentioned chip away from a surface of the above-mentioned temporary substrate. The above-mentioned barrier member includes a plurality of openings provided at intervals, and projections of the above-mentioned openings on the above-mentioned temporary substrate are located within an intermediate region in one-to-one correspondence. The above-mentioned intermediate region is a surface region of the above-mentioned temporary substrate between the above-mentioned adjacent two chips. A solvent is injected from the above-mentioned opening between the above-mentioned adjacent two chips, so that the above-mentioned solvent dissolves the portion of the above-mentioned first adhesive layer so as to form the above-mentioned plurality of weakened structures. The method is more easily implemented, and forming the weakened structure of a predetermined size and a predetermined shape may be further ensured at the same time.

It is to be noted that the solvent in the application is matched with a material of the corresponding first adhesive layer, that is, the solvent is a material that can remove the first adhesive layer. In a specific embodiment, a material of the above-mentioned first adhesive layer is adhesive material including Polyimide (PI) backbone, and correspondingly, the solvent is an organic solvent such as N-methylpyrrolidone (NMP). In the actual application process, the corresponding solvent may be determined according to the material of the corresponding first adhesive layer.

The openings in the above-mentioned scheme are in one-to-one correspondence with the intermediate regions, in fact, the way of setting or arranging the opening corresponds to the way of setting or arranging the chip on the temporary substrate. If the chips on the temporary substrate are distributed in matrix, then correspondingly, the openings on the barrier member are also distributed in matrix. If there is only one row of the chips on the temporary substrate (the number of chips is more than three), then correspondingly, there is only one row of openings on the barrier member.

The shape of the weakened structure of the application is not limited to a trapezoidal cross sectional shape shown in FIG. 5, it may also be other shapes, such as a rectangular solid, a triangular prism, a triangular pyramid, or a cylinder, etc. The specific shape may be determined by controlling manufacturing parameter such as the time of removing the first adhesive layer, etc. Further, the size of the weakened structure may also be controlled by controlling the parameter such as the time of removing the first adhesive layer.

In the actual application process, a pulling force between the weakened structure 31 that is close to an end (the left end in FIG. 7, the judgment of left and right is made when facing the screen) applied by the first predetermined force and the chip 42 is relatively large, the pulling force between the weakened structure 31 and the chip 42 gradually decreases in a direction that is away from the end applied by the first predetermined force, and the pulling force between the weakened structure 31 on the other end (the right end in FIG. 7) and the chip 42 is at a minimum. In order to further ensure that applying a relatively small first predetermined force may ensure that all of the weakened structures 31 and the corresponding chips 42 may be easily disengaged. In one embodiment of the application, in a first predetermined direction, the cross-sectional area of the above-mentioned opening perpendicular onto the second surface gradually increases. The above-mentioned first predetermined direction is a direction from the end of the above-mentioned transfer substrate 21 applied by the above-mentioned first predetermined force to the other end of the above-mentioned transfer substrate 21. In this way, the size of the formed weakened structure 31 gradually decreases along the first predetermined direction so that in the first predetermined direction, the force required to disengage the weakened structure 31 from the corresponding chip 42 gradually decreases, thereby further ensuring that applying the relatively small first predetermined force may better disengage all the weakened structures 31 from the corresponding chips 42.

In another embodiment of the application, the operation of applying a second adhesive layer on the above-mentioned transfer head 22 and the above-mentioned chip 42 of the above-mentioned temporary substrate 10 being adhered by the above-mentioned second adhesive layer includes the following operations. The above-mentioned second adhesive layer on the above-mentioned transfer head 22 is aligned with the above-mentioned chip 42 so that the above-mentioned third surface 201 is parallel to the above-mentioned first surface 11, and the above-mentioned fourth surface 202 is parallel to the above-mentioned second surface 12. A second predetermined force is applied to the above-mentioned transfer device 20 so that the above-mentioned second adhesive layer is adhered to the above-mentioned chip 42 on the above-mentioned temporary substrate 10, as shown in FIG. 8 (The second adhesive layer is not shown in figures). In this method, it can be further ensured that the transfer device is accurately adhered to a predetermined chip through the second adhesive layer, so that the accuracy of subsequent transfer processes may be further ensured.

In yet another embodiment of the application, the operation of applying the first predetermined force to the predetermined end of the above-mentioned transfer device 20 so that the above-mentioned weakened structure 31 is broken, and then the above-mentioned chip 42 after disengaged from the above-mentioned temporary substrate 10 being transferred onto the above-mentioned transfer device 20 includes the following operations. The above-mentioned first predetermined force is applied to a first end on the above-mentioned transfer substrate 21 so that the above-mentioned transfer substrate 21 begins to rotate about a predetermined axis so that the above-mentioned weakened structures 31 are subsequently broken in ascending order of a distance from the first end of the above-mentioned transfer substrate 21. The thickness of a first end of the above-mentioned temporary substrate 10 is less than the one of a second end of the above-mentioned temporary substrate 10. The above-mentioned predetermined axis is on a plane where the above-mentioned third surface 201 is located and is perpendicular to a sidewall of the above-mentioned transfer substrate 21. In this way, the first end of the transfer substrate 21 is an end corresponding to the first end of the temporary substrate 10. The first predetermined force is applied to the first end of the transfer substrate 21, so that the weakened structure 31 that is located at a place of the temporary substrate 10 whose thickness is relatively small is firstly disengaged from the corresponding chip 42, as shown in FIG. 7. This makes it possible to adopt a smaller predetermined force to disengage the weakened structure from the corresponding chip.

Further, in the actual application process, the shape of the above-mentioned transfer substrate 21 may be completely matched with the shape of the temporary substrate 10, as shown in FIG. 2, that is, the above-mentioned transfer substrate 21 has a third surface 201 and a fourth surface 202 opposite to each other, and there is a second angle between the above-mentioned fourth surface 202 and the above-mentioned third surface 201. The above-mentioned second angle is greater than 0° and less than 90°. The above-mentioned plurality of transfer heads 22 are located at intervals on the above-mentioned fourth surface 202, and the above-mentioned first angle is equal to the above-mentioned second angle.

In the actual application process, the operation of the chip 42 on the growth substrate 41 being adhered, by using the above-mentioned first adhesive layer 30, onto the above-mentioned temporary substrate 10 includes the following operations. A chip source structure 40 is attached to the above-mentioned first adhesive layer 30 so that the above-mentioned chip 42 in the above-mentioned chip source structure 40 is adhered onto the surface of the above-mentioned first adhesive layer 30, as shown in FIG. 3. The above-mentioned chip source structure 40 includes the above-mentioned growth substrate 41 and the above-mentioned plurality of chips 42 provided on the above-mentioned growth substrate 41. The above-mentioned growth substrate 41 is removed so as to obtain the structure shown in FIG. 4.

The above-mentioned growth substrate may be any feasible growth substrate in the conventional art, such as a sapphire growth substrate, a GaN growth substrate, or the like. Those skilled in the art may choose a suitable transfer substrate according to the actual situation.

The method of removing the above-mentioned growth substrate of the application may be selected according to the actual situation, for example, it may be determined according to specific materials of the growth substrate. In a specific embodiment of the application, the above-mentioned growth substrate is a sapphire growth substrate. The operation of removing the above-mentioned growth substrate includes the following operations. The above-mentioned growth substrate is irradiated by a laser so as to remove a corresponding Ga, and the above-mentioned growth substrate after irradiated by the laser is peeled.

A yet another embodiment of the application, the operation of transferring the above-mentioned chip 42 on the above-mentioned transfer device 20 onto the predetermined structure 50 includes the following operations. The above-mentioned transfer device 20 provided with the above-mentioned chip 42 is bonded to the above-mentioned predetermined structure 50, and the above-mentioned chip 42 is in contact with the above-mentioned predetermined structure 50, as shown in FIG. 8, and the above-mentioned transfer device 20 is removed so as to form the structure shown in FIG. 9.

It is to be noted that the chip in the application may be any chip required to be transferred in the conventional art. Those skilled in the art may apply, according to the actual situation, the transfer method and the transfer system of the application in suitable chip transfer processes.

In another embodiment of the application, the above-mentioned chip includes at least one of an LED chip, a Micro LED chip, and a Mini LED chip. That is, the above-mentioned transfer method and the above-mentioned transfer system are applied in these chip transfer processes.

In a specific embodiment of the application, the above-mentioned predetermined structure includes a display back plate. It is also to be noted that the predetermined structure in the application is not limited to the above-mentioned display back plate. The corresponding predetermined structure may be specifically determined according to the actual situation.

It should be understood that the applications of the disclosure are not limited to the above-mentioned examples, and one of ordinary skill in the art may improve or transform in accordance with the above description, all of these improvements and transformations should belong to the scope of the appended claims of the disclosure.

1. A transfer system, the transfer system being configured to transfer a chip, comprising:
a temporary substrate, having a first surface and a second surface opposite to each other, there being a first angle between the second surface and the first surface, the first angle being greater than 0° and less than 90°; and
a transfer device, having a transfer substrate and a plurality of transfer heads provided on the transfer substrate, the transfer substrate having a third surface and a fourth surface opposite to each other, and there being a second angle between the fourth surface and the third surface, the second angle being greater than 0° and less than 90°, the plurality of transfer heads being located at intervals on the fourth surface, and a side surface of the transfer head that faces away from the transfer substrate being parallel to the fourth surface.

2. The transfer system according to claim 1, wherein the first angle is equal to the second angle.

3. A chip transfer method, the chip transfer method being applied to the transfer system as claimed in claim 1, wherein the chip transfer method comprises:
a first adhesive layer being formed on the second surface of the temporary substrate, a chip on a growth substrate being adhered, by the first adhesive layer, onto the temporary substrate;
the first adhesive layer adhered to the chip being made into a plurality of weakened structures;
a second adhesive layer being applied on the transfer head, the chip on the temporary substrate being adhered by the second adhesive layer; and
a first predetermined force being applied to a predetermined end of the transfer device so that the weakened structures are broken, and thus the chip after disengaged from the temporary substrate being transferred onto the transfer device;
the chip on the transfer device being transferred onto a predetermined structure.

4. The transfer method according to claim 3, wherein the first adhesive layer adhered to the chip being made into the plurality of weakened structures comprises:
removing a portion of the first adhesive layer so that the remaining first adhesive layer forms the plurality of weakened structures.

5. The transfer method according to claim 4, wherein removing the portion of the first adhesive layer so that the remaining first adhesive layer forms the plurality of weakened structures comprises:
a barrier member being provided on a surface of the chip away from the temporary substrate, the barrier member comprises a plurality of openings provided at intervals, and projections of the openings on the temporary substrate being located within an intermediate region in one-to-one correspondence, the intermediate region being a surface region of the temporary substrate between the adjacent two chips;
a solvent being injected from the opening between the adjacent two chips, so that the solvent dissolves the portion of the first adhesive layer so as to form the plurality of weakened structures.

6. The transfer method according to claim 5, wherein a sectional area of the opening in a direction perpendicular to the second surface gradually increases.

7. The transfer method according to claim 3, wherein a second adhesive layer being applied on the transfer head, the chip on the temporary substrate being adhered by the second adhesive layer comprises:
the second adhesive layer on the transfer head being aligned with the chip so that the third surface is parallel to the first surface, and the fourth surface is parallel to the second surface;
a second predetermined force being applied to the transfer device, so that the second adhesive layer is adhered to the chip on the temporary substrate.

8. The transfer method according to claim 3, wherein the first predetermined force being applied to a predetermined end of the transfer device so that the weakened structures are broken and thus the chip after disengaged from the temporary substrate is transferred onto the transfer device comprises:
the first predetermined force being applied to a first end on the transfer substrate so that the transfer substrate begins to rotate about a predetermined axis, and the weakened structures are subsequently broken in ascending order of a distance from the first end of the transfer substrate, the thickness of a first end of the temporary substrate being less than the one of a second end of the temporary substrate, the predetermined axis being on a plane where the third surface is located and is perpendicular to a sidewall of the transfer substrate.

9. The transfer method according to claim 3, wherein the chip on the growth substrate being adhered, by using the first adhesive layer, onto the temporary substrate comprises:
a chip source structure being attached to the first adhesive layer so that the chip in the chip source structure is adhered to a surface of the first adhesive layer, wherein the chip source structure comprises the growth substrate and the plurality of chips provided on the growth substrate;
removing the growth substrate.

10. The transfer method according to claim 9, wherein the growth substrate is a sapphire growth substrate, the removing the growth substrate comprises:
irradiating, by adopting a laser, the growth substrate;
peeling the growth substrate after irradiated by the laser.

11. The transfer method according to claim 3, wherein the chip on the transfer device being transferred onto a predetermined structure comprises:
the transfer device provided with the chip being bonded to the predetermined structure, and the chip being in contact with the predetermined structure;
removing the transfer device.

12. The transfer method according to claim 3, wherein the predetermined structure comprises a display back plate.

13. The transfer method according to claim 3, wherein the chip comprises at least one of a Light Emitting Diode (LED) chip, a Micro LED chip, and a Mini LED chip.

14. A chip transfer method, the chip transfer method being applied to the transfer system as claimed in claim 2, wherein the chip transfer method comprises:
a first adhesive layer being formed on the second surface of the temporary substrate, a chip on a growth substrate being adhered, by the first adhesive layer, onto the temporary substrate;
the first adhesive layer adhered to the chip being made into a plurality of weakened structures;
a second adhesive layer being applied on the transfer head, the chip on the temporary substrate being adhered by the second adhesive layer; and
a first predetermined force being applied to a predetermined end of the transfer device so that the weakened structures are broken, and thus the chip after disengaged from the temporary substrate being transferred onto the transfer device;
the chip on the transfer device being transferred onto a predetermined structure.

15. The transfer method according to claim 4, wherein the first predetermined force being applied to a predetermined end of the transfer device so that the weakened structures are broken and thus the chip after disengaged from the temporary substrate is transferred onto the transfer device comprises:
the first predetermined force being applied to a first end on the transfer substrate so that the transfer substrate begins to rotate about a predetermined axis, and the weakened structures are subsequently broken in ascending order of a distance from the first end of the transfer substrate, the thickness of a first end of the temporary substrate being less than the one of a second end of the temporary substrate, the predetermined axis being on a plane where the third surface is located and is perpendicular to a sidewall of the transfer substrate.

16. The transfer method according to claim 5, wherein the first predetermined force being applied to a predetermined end of the transfer device so that the weakened structures are broken and thus the chip after disengaged from the temporary substrate is transferred onto the transfer device comprises:
the first predetermined force being applied to a first end on the transfer substrate so that the transfer substrate begins to rotate about a predetermined axis, and the weakened structures are subsequently broken in ascending order of a distance from the first end of the transfer substrate, the thickness of a first end of the temporary substrate being less than the one of a second end of the temporary substrate, the predetermined axis being on a plane where the third surface is located and is perpendicular to a sidewall of the transfer substrate.

17. The transfer method according to claim 6, wherein the first predetermined force being applied to a predetermined end of the transfer device so that the weakened structures are broken and thus the chip after disengaged from the temporary substrate is transferred onto the transfer device comprises:
the first predetermined force being applied to a first end on the transfer substrate so that the transfer substrate begins to rotate about a predetermined axis, and the weakened structures are subsequently broken in ascending order of a distance from the first end of the transfer substrate, the thickness of a first end of the temporary substrate being less than the one of a second end of the temporary substrate, the predetermined axis being on a plane where the third surface is located and is perpendicular to a sidewall of the transfer substrate.

18. The transfer method according to claim 7, wherein the first predetermined force being applied to a predetermined end of the transfer device so that the weakened structures are broken and thus the chip after disengaged from the temporary substrate is transferred onto the transfer device comprises:
the first predetermined force being applied to a first end on the transfer substrate so that the transfer substrate begins to rotate about a predetermined axis, and the weakened structures are subsequently broken in ascending order of a distance from the first end of the transfer substrate, the thickness of a first end of the temporary substrate being less than the one of a second end of the temporary substrate, the predetermined axis being on a plane where the third surface is located and is perpendicular to a sidewall of the transfer substrate.

19. The transfer method according to claim 4, wherein the chip on the growth substrate being adhered, by using the first adhesive layer, onto the temporary substrate comprises:
a chip source structure being attached to the first adhesive layer so that the chip in the chip source structure is adhered to a surface of the first adhesive layer, wherein the chip source structure comprises the growth substrate and the plurality of chips provided on the growth substrate;
removing the growth substrate.

20. The transfer method according to claim 4, wherein the chip on the transfer device being transferred onto a predetermined structure comprises:
the transfer device provided with the chip being bonded to the predetermined structure, and the chip being in contact with the predetermined structure;
removing the transfer device.
